(19) United States
(12) Patent Application Publication
(10) Pub. No.: US 2009/0316340 A1
(43) Pub. Date: Dec. 24, 2009

(54) Device, portable terminal device, and rotative supporting unit

(75) Inventors: Fumio Mitamura, Kawasaki (JP); Kazunori Katou, Kawasaki (JP); Yasuyuki Kitada, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/379,780

(22) Filed: Feb. 27, 2009

(30) Foreign Application Priority Data
Jun. 24, 2008 (JP) 2008-165148

(51) Int. Cl. H05K 5/00

(52) U.S. Cl. 361/679.01

(57) ABSTRACT

A device includes: a first housing that has a wall portion protruding from the front face side thereof; a second housing that has a portion pressed against the wall portion, and is overlapped on the front face side of the first housing, the second housing being rotatable, with the portion being pressed against the wall portion; a first member that is attached to a face of the first housing, the face facing the second housing; a second member that is attached to a face of the second housing, the face facing the face having the first member attached thereto; a rotary shaft unit that allows the second member to slidably move with respect to the first member, and supports the second member in a rotatable manner; and a pushing unit that pushes the second housing, so that the portion of the second housing is pressed against the wall portion. In this device, the first member has a guide groove that has the rotary shaft unit slidably attached thereto. The rotary shaft unit moves away from the wall portion or approaches the wall portion when the second housing rotates, with the portion being pressed against the wall portion.

### CROSS-REFERENCE TO RELATED APPLICATION

This application is based upon and claims the benefit of priority of the prior Japanese Patent Application No. 2008-165148, filed on Jun. 24, 2008, the entire contents of which are incorporated herein by reference.

### FIELD

The present embodiments relate to a device that has a second housing rotatably connected to a first housing, and also relates to a portable terminal device and a rotative supporting unit.

### BACKGROUND

Various kinds of portable terminal devices have been known. For example, there have been known portable telephone devices each having a first housing and a second housing, or a main housing and a display housing. Various improvements have been made on those portable telephone devices, so as to achieve reductions in size and thickness.

As the amount of information to be displayed has increased with the recent increases in communication speed and display resolution, portable telephone devices that can receive television broadcasting services are available today. In this trend, there is an increasing demand for devices that can switch the display orientation of an image or a video image displayed on the display unit attached to the display housing between a vertical display orientation and a horizontal display orientation.

When the orientation of an image or a video image displayed on a display unit is switched between a vertical display orientation and a horizontal display orientation, the display housing is rotated with respect to the main housing. Various supporting mechanisms that can rotate display housings with respect to main housings have been suggested. For example, there has been a rotative supporting mechanism that includes an eccentric cam having a closed position portion and an open position portion, and a pressing unit that stops rotation of the eccentric cam (see Japanese Patent Application Publication No. 2005-106278).

### SUMMARY

According to an aspect of the present invention, there is provided a device that includes: a first housing that has a wall portion protruding from the front face side thereof; a second housing that has a portion pressed against the wall portion, and is overlapped on the front face side of the first housing, the second housing being rotatable, with the portion being pressed against the wall portion; a first member that is attached to a face of the first housing, the face facing the second housing; a second member that is attached to a face of the second housing, the face facing the face having the first member attached thereto; a rotary shaft unit that allows the second member to slidably move with respect to the first member, and supports the second member in a rotatable manner; and a pushing unit that pushes the second housing, so that the portion of the second housing is pressed against the wall portion. In this device, the first member has a guide groove that has the rotary shaft unit slidably attached thereto. The rotary shaft unit moves away from the wall portion or approaches the wall portion when the second housing rotates, with the portion being pressed against the wall portion.

### BRIEF DESCRIPTION OF DRAWINGS

FIGS. 1A through 1C are perspective views depicting situations where the display housing of a portable telephone device in accordance with a first embodiment of the present invention is opened and closed;

FIG. 2 is an exploded view of the rotative supporting unit of the portable telephone device depicted in FIGS. 1A through 1C;

FIG. 3 depicts the rotative supporting unit in an assembled state, seen from the front face side;

FIG. 4 depicts the rotative supporting unit in an assembled state, seen from the back face side;

FIG. 5 is a cross-sectional view of the rotative supporting unit, taken along the line A-A of FIG. 3;

FIG. 6 illustrates a situation where the rotary shaft unit slides along the guide groove;

FIG. 7 illustrates a situation where the second member rotates counterclockwise;

FIG. 8 illustrates a situation where the second member rotates clockwise;

FIG. 9A is a schematic view of the portable telephone device, seen from the front face side;

FIG. 9B is an enlarged cross-sectional view of the portable telephone device, taken along the line B-B of FIG. 9A;

FIG. 10 is a schematic functional block diagram of the portable telephone device;

FIGS. 11A through 11C illustrate situations where the magnetic sensor detects display orientations;

FIG. 12A illustrates a situation where the display housing is rotating;

FIG. 12B is a right-side view of the portable telephone device, with the display housing being closed;

FIGS. 13A through 13C illustrate situations where the display housing of the portable telephone device of the first embodiment is opened and closed;

FIGS. 14A through 14D are four side views of a portable telephone device in accordance with a second embodiment of the present invention;

FIG. 15 is a back side view of the display housing of the second embodiment;

FIGS. 16A through 16C illustrate situations where the display housing of the portable telephone device of the second embodiment is opened and closed;

FIGS. 17A through 17D are four side views of a portable telephone device in accordance with a third embodiment of the present invention;

FIGS. 18A through 18C illustrate situations where the display housing of the portable telephone device of the third embodiment is opened and closed; and

FIG. 19 is a conceptual diagram illustrating a situation where the peripheral portion of the display housing is engaged with a groove formed in the wall portion.

### DESCRIPTION OF EMBODIMENTS

The following is a description of preferred embodiments of the present invention, with reference to the accompanying drawings. It should be noted that the sizes and ratios of the components illustrated in the drawings may not be exactly the same as the actual sizes and ratios. Also, some details are omitted from the drawings.

### First Embodiment

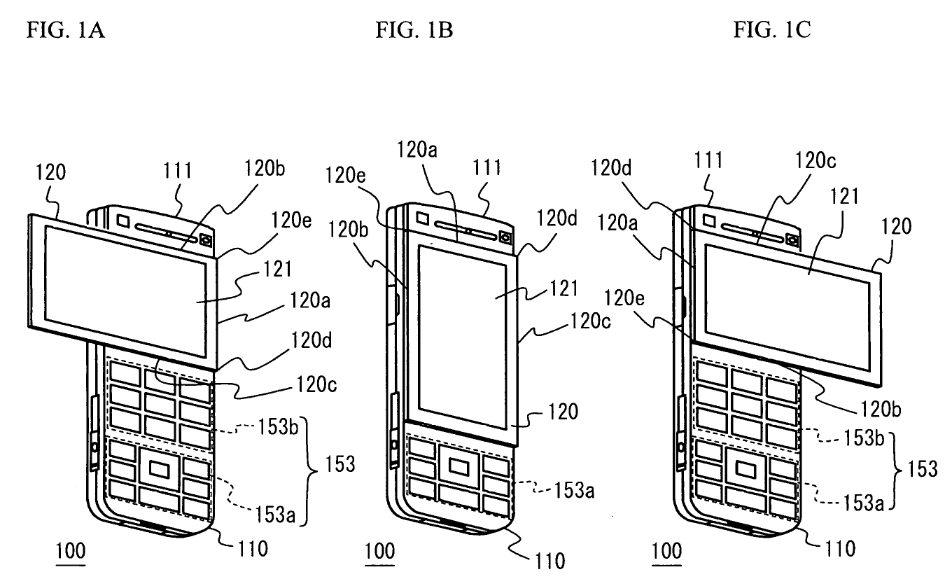

Referring first to FIGS. 1A through 1C, which are perspective views of a portable telephone device 100 as an example of a device and a portable terminal device of the present invention, the structure and operations of the portable telephone device 100 are now briefly described. The structure and operations of the portable telephone device 100 will be described later in detail.

The portable telephone device 100 includes a main housing 110 equivalent to the first housing, and a display housing 120 that is equivalent to the second housing and has a display 121. The main housing 110 has a wall portion 111 that protrudes from the upper end portion on the surface side of the main housing 110. The display housing 120 is overlapped on the surface side of the first housing 110, so that the display housing 120 can be rotatively moved while corner portions 120d and 120e are pushed against the wall portion 111. The display housing 120 is connected to the main housing 110. FIG. 1A depicts a situation where the display housing 120 is closed with respect to the main housing 110. FIG. 1B depicts a situation where the display housing 120 is rotated and opened counterclockwise with respect to the main housing 110. FIG. 1C depicts a situation where the display housing 120 is rotated and opened clockwise with respect to the main housing.

When the display housing 120 is closed as depicted in FIG. 1A, the upper periphery 120a of the display housing 120 is pressed against the wall portion 111. When the display housing 120 is opened as depicted in FIG. 1B, the right-side periphery 120c of the display housing 120 is pressed against the wall portion 111. When the display housing 120 is opened as depicted in FIG. 1C, the left-side periphery 120b of the display housing 120 is pressed against the wall portion 111.

Next, the structure and operations of the portable telephone device 100 are described in detail.

### <Rotative Supporting Mechanism>

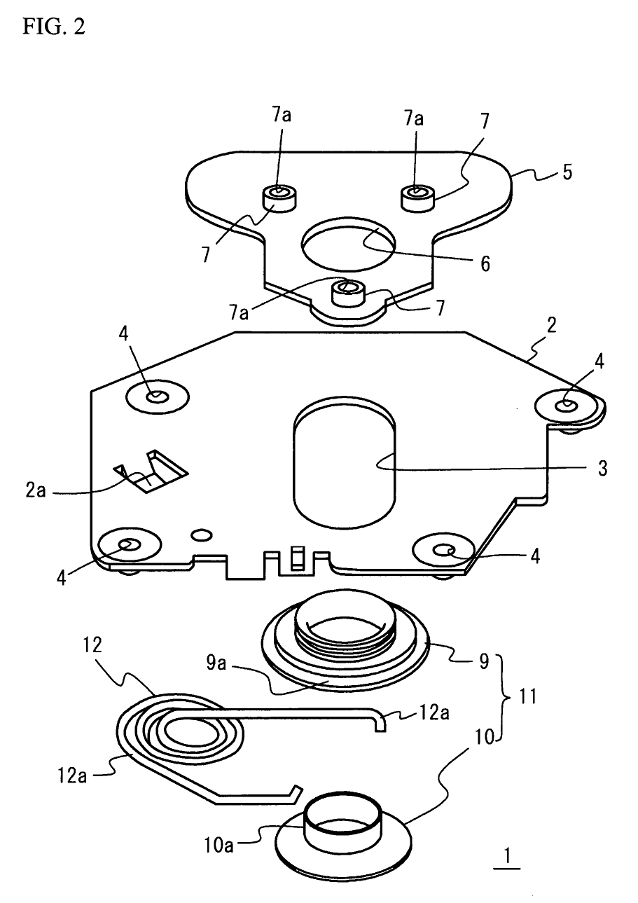

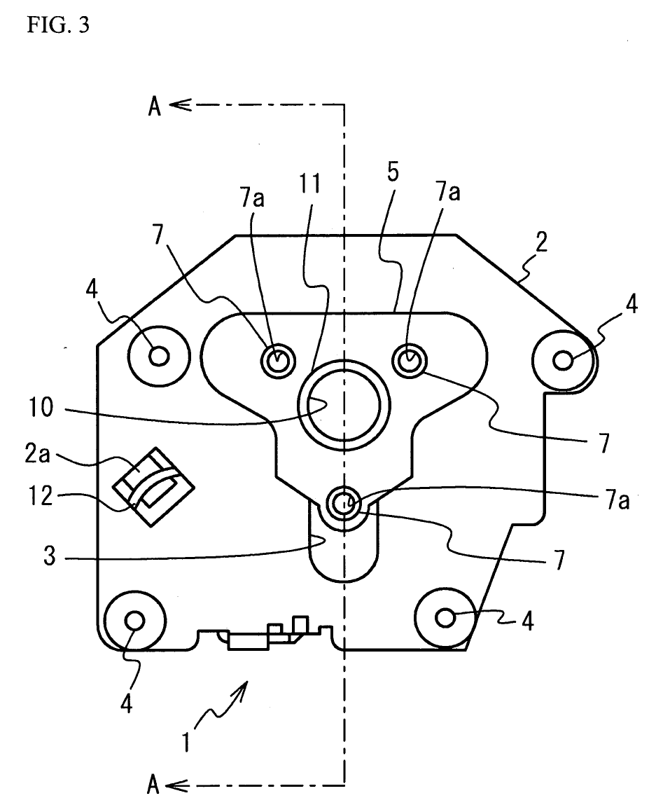

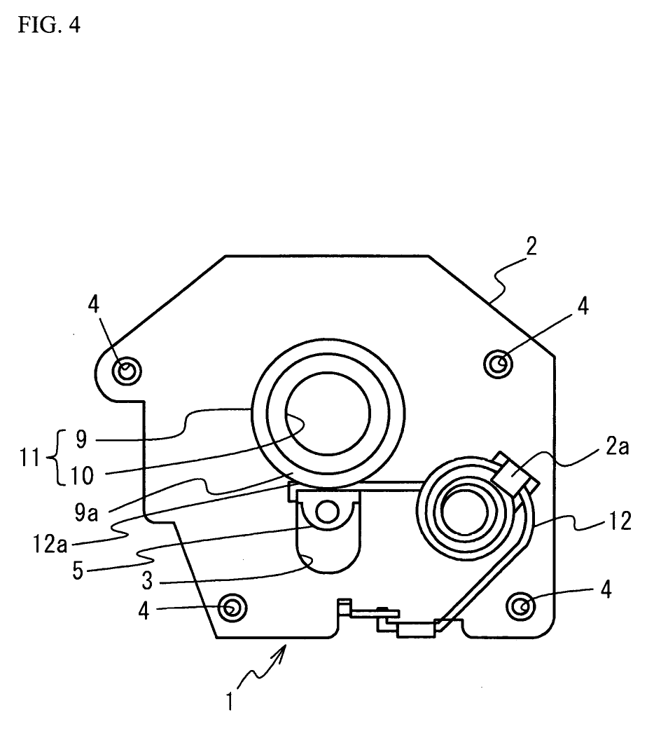

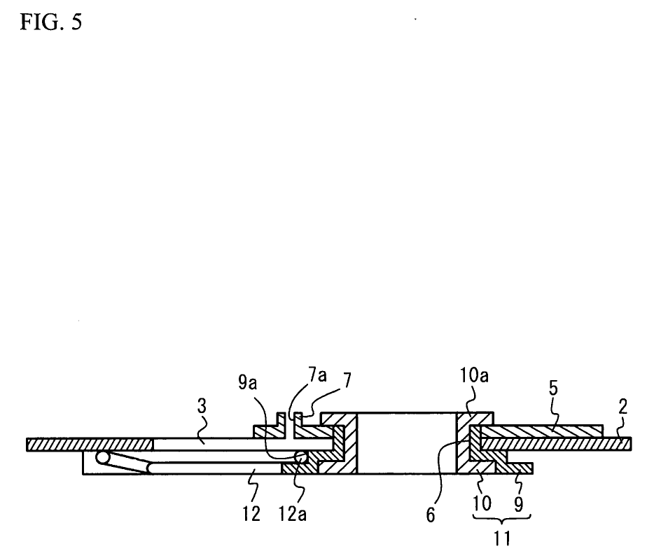

FIG. 2 is an exploded view of a rotative supporting unit 1. The rotative supporting unit 1 is used to connect the display housing 120 to the main housing 110, so that the corner portions 120d and 120e are rotatively pressed against the wall portion 111. FIG. 3 depicts the rotative supporting unit 1 in an assembled state, seen from the front face side. FIG. 4 depicts the rotative supporting unit 1 in an assembled state, seen from the back face side. FIG. 5 is a cross-sectional view of the rotative supporting unit 1, taken along the line A-A of FIG. 3.

The rotative supporting unit 1 includes a face of the main housing 110 that faces the display housing 120, or a first member 2 attached to the front face side of the main housing 110. The first member 2 is a plate-like member, and has a straight guide groove 3. The later described rotary shaft unit 11 is slidably attached to the guide groove 3. The guide groove 3 guides the rotary shaft unit 11 that moves away from or approaches the wall portion 111 as the display housing 120 revolves, with the corner portion 120d or the corner portion 120e of the display housing 120 being pressed against the wall portion 111.

Screw holes 4 for attachment to the main housing 110 are formed at the peripheral portion of the first member 2. A claw-like attachment piece 2a for engagement with the later described spring unit 12 is also formed in the first member 2. The first member 2 is screwed to the main housing 110, so that the wall portion 111 is positioned on a line extending from the guide groove 3.

The rotative supporting unit 1 also includes a face that faces the face of the display housing 120 to which the first member 2 is attached, or a second member 5 attached to the back face side of the display housing 120. The second member 5 is a plate-like member, and has a shaft hole 6. Protrusions 7 for attachment to the display housing 120 are also provided around the shaft hole 6, and screw holes 7a are formed in the respective protrusions 7. The second member 5 is attached to the display housing 120 by engaging the protrusions with attachment holes (not depicted) formed in the display housing 120 and screwing the protrusions 7 into the attachment holes. The second member 5 is placed on the front face side of the first member 2.

The rotative supporting unit 1 includes a resin sliding ring 9 and a metallic clamping ring 10 that is to be combined with the sliding ring 9. The combination of the sliding ring 9 and the clamping ring 10 forms the rotary shaft unit 11.

The clamping ring 10 has a cylindrical portion 10a, and the cylindrical portion 10a is engaged with the inner periphery of the sliding ring 9, so as to form the rotary shaft unit 11. The rotary shaft unit 11 is inserted into the guide groove 3, from the back face side of the first member 2. The rotary shaft unit 11 is further inserted into the shaft hole 6 formed in the second member 5. The upper peripheral portion of the cylindrical portion 10a is exposed through the front face side of the second member 5, and the exposed upper peripheral portion is clamped. In this manner, the rotary shaft unit 11 and the second member 5 are integrated. Here, the rotary shaft unit 11 is not fixed to the first member 2. Accordingly, the rotary shaft unit 11 rotatively supports the second member 5 with respect to the first member 2, and is slidably attached to the guide groove 3. As a result, the rotary shaft unit 11 can approach the wall portion 111 and move away from the wall portion 111.

The sliding ring 9 has a retainer portion 9a for retaining the later described spring member 12. The retainer portion 9a is placed on the back face side of the first member 2.

The rotative supporting unit 1 includes the spring member 12 that is an example of a pushing means. The spring member 12 is formed by shaping a metal wire into a spiral. The spring member 12 is engaged with the attachment piece 2a, and is placed on the back face side of the first member 23. The end portions 12a of the spring member 12 are retained by the retainer portion 9a formed on the sliding ring 9. Accordingly, the second member 5 is pushed via the rotary shaft unit 11. The pushing direction is one of the directions in which the guide groove 3 for helping the sliding movement of the rotary shaft unit 11 extends, or the direction in which the rotary shaft unit 11 approaches the wall portion 111.

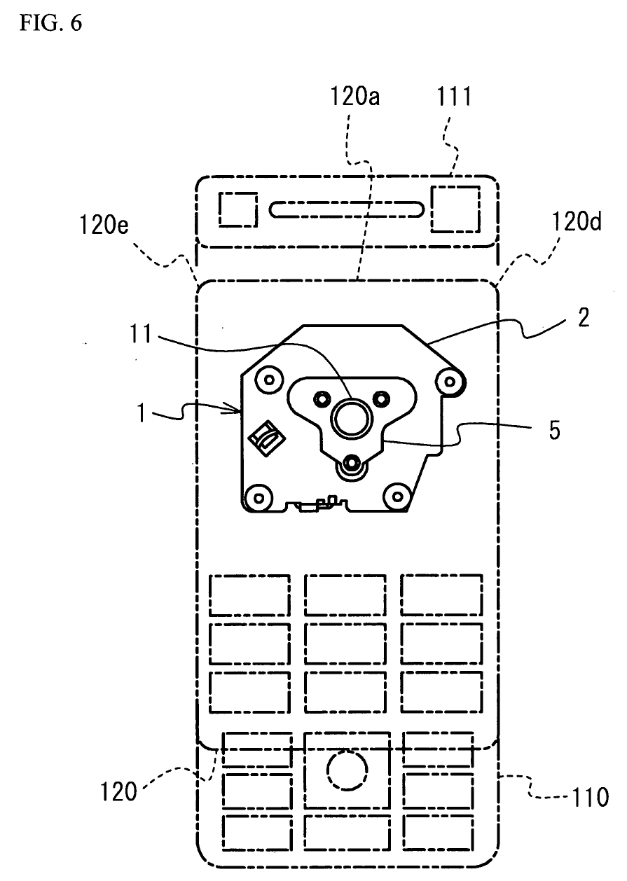

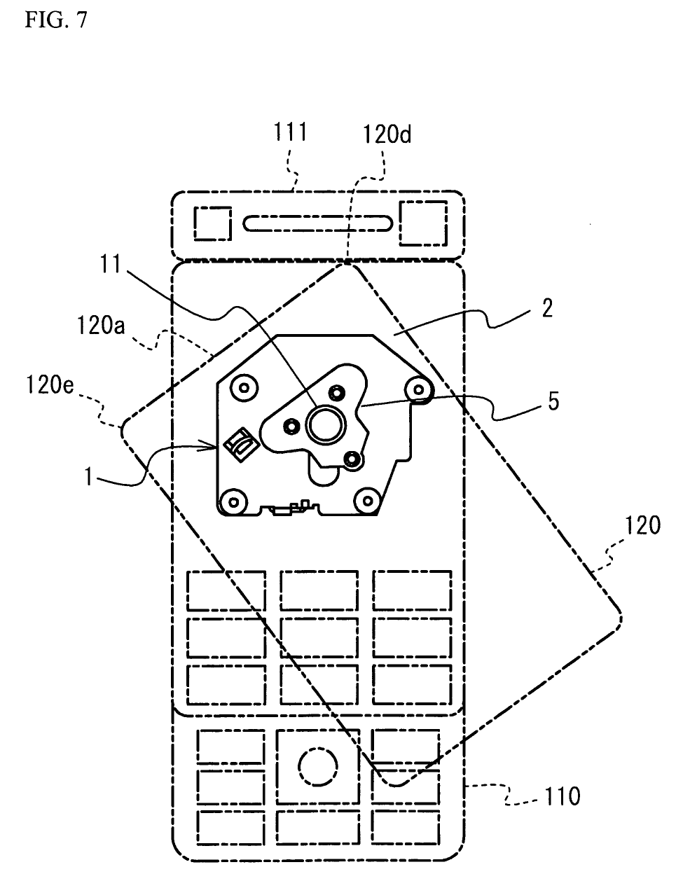

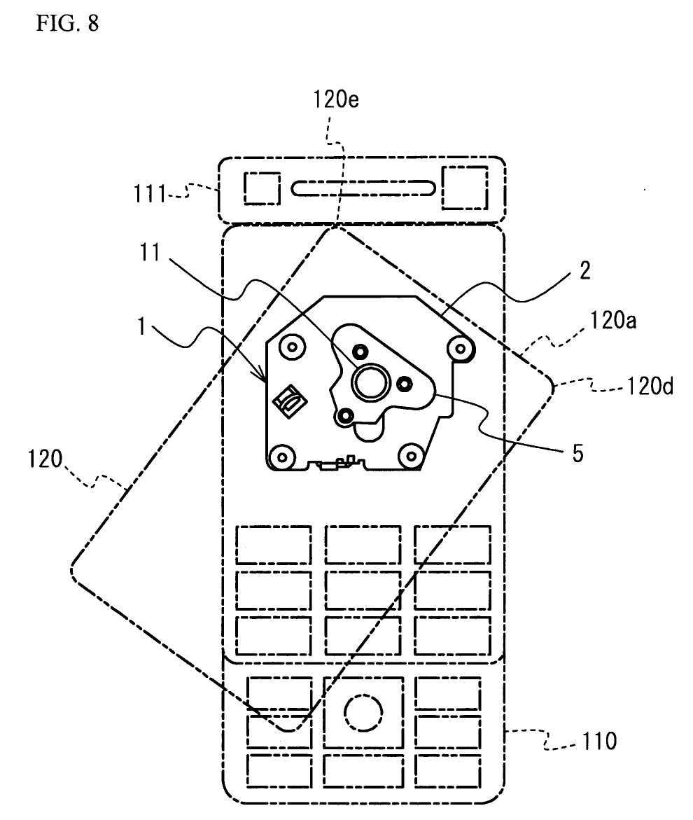

FIG. 6 illustrates a situation where the rotary shaft unit 11 has slid along the guide groove 3 and moved away from the wall portion 111. The movement of the rotary shaft unit 11 away from the wall portion 111 is caused by the pushing force generated from the spring member 12. As the rotary shaft unit 11 moves away from the wall portion 111, the second member 5 can also move away from the wall portion 111. FIG. 7 illustrates a situation where the rotary shaft unit 11 rotates counterclockwise while moving away from the wall portion 111. FIG. 8 illustrates a situation where the rotary shaft unit 11 rotates clockwise while moving away from the wall portion 111. In this manner, the rotative supporting unit 1 can cause the rotary shaft unit 11 to rotate while moving the rotary shaft unit 11 away from the wall portion 111. As a result, the display housing 120 to which the second member 5 integrated with the rotary shaft unit 11 is attached can rotate, with the corner portions 120d and 120e being pressed against the wall portion 111. When the contact positions of the corner portions 120d and 120e with respect to the wall portion 111 go beyond predetermined positions, the rotary shaft unit 11 starts approaching the wall portion 111.

The thickness of the rotative supporting unit 1 is equal to the sum of the thicknesses of the first member 2 and the second member 5, which is very thin.

### <Main Housing>

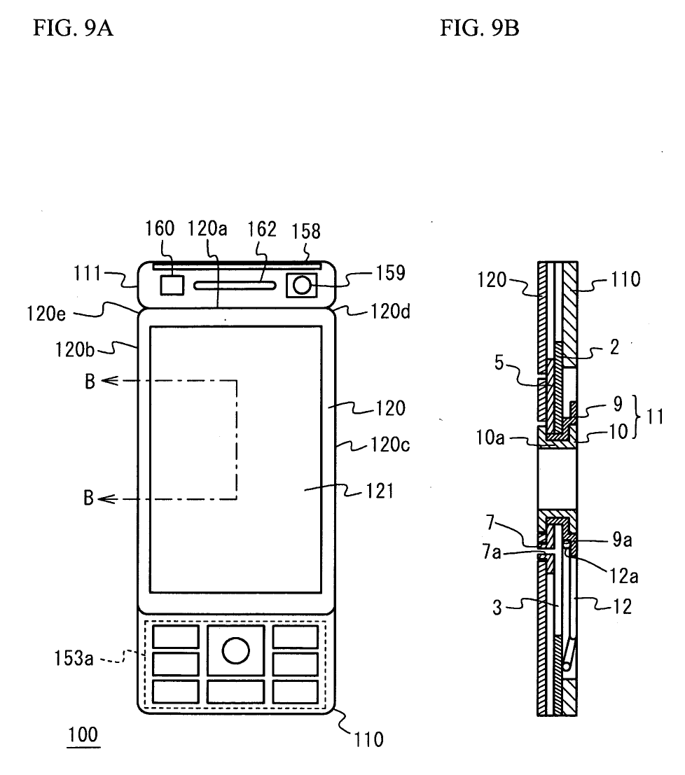

FIG. 9A is a schematic view of the portable telephone device 100, seen from the front side. FIG. 9B is an enlarged cross-sectional view of the portable telephone device, taken along the line B-B of FIG. 9A. As is apparent from FIG. 9A, the main housing 110 includes the wall portion 111 protruding from the upper peripheral portion on the front face side. The first member 2 is attached to the main housing 110, so that the extending direction of the guide groove 3 matches the longitudinal direction of the main housing 110. The display housing 120 is pressed against the wall portion 111 by the pushing force of the spring member 12 via the rotary shaft unit 11 and the second member 5.

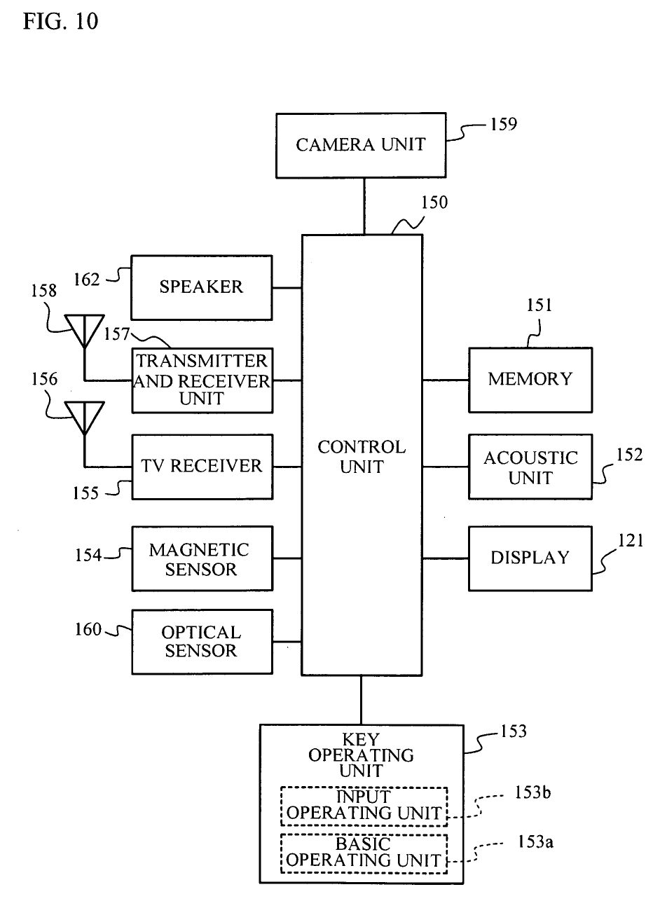

FIG. 10 is a schematic functional block diagram of the portable telephone device 100. A control unit 150 is provided in the main housing 110. A memory 151, an acoustic unit 152, a key operating unit 153, and a magnetic sensor 154 are connected to the control unit 150. A television (TV) receiver 155, a transmitter and receiver unit 157, and a camera unit 159 are also connected to the control unit 150. An antenna 156 for television is connected to the TV receiver 155. An antenna 158 for wireless communications is connected to the transmitter and receiver unit 157. An optical sensor 160 that senses the illuminance of the surroundings is further connected to the control unit 150. A speaker 162 is also connected to the control unit 150. A display 121 is also connected to the control unit 150. The display 121 is placed in the display housing 120.

Other than the display 121, the above components connected to the control unit 150 are housed in the main housing 110. As depicted in FIG. 9A, among the components housed in the main housing 110, the speaker 162 is built in the wall portion 111. The wireless communication antenna 158, the camera unit 159, and the optical sensor 160 are also built in the wall portion 111.

As depicted in FIGS. 1A through 1C, the key operating unit 153 is provided on the front face of the main housing 110. The key operating unit 153 is divided into a basic operating unit 153a and an input operating unit 153b.

Keys (buttons) for starting various functions, such as a power key, a mail function start-up key, a call function start-up key, and a telephone-book function start-up key, are collectively arranged on the basic operating unit 153a. The basic operating unit 153a is formed on the front face side of the main housing 110 and on the lower peripheral side of the main housing 110. As depicted in FIG. 1A, the basic operating unit 153a is exposed and can be operated, even when the display housing 120 is closed.

Numeric and character input keys are arranged on the input operating unit 153b. The input operating unit 153b is placed on the front face side of the main housing 110 and on the upper side of the basic operating unit 153a. As depicted in FIG. 1A, the input operating unit 153b is hidden behind the display housing 120, when the display housing 120 is closed. As depicted in FIGS. 1B and 1C, the input operating unit 153b is exposed and can be operated, when the display housing 120 is open.

The basic operating unit 153a and the input operating unit 153b are both placed on the upper face side of the main housing 110, and are located substantially at the same height, so that the respective keys have excellent operability.

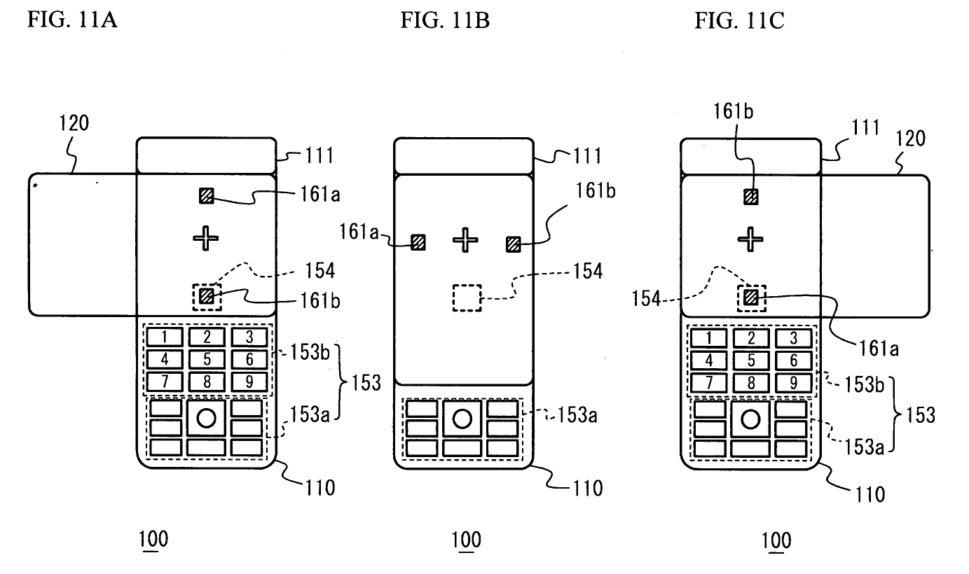

FIGS. 11A, 11B, and 11C illustrate display orientation detection by the magnetic sensor 154. The display housing 120 can rotate. Therefore, the display orientation of an image or a video image displayed on the display 121 is required to be switched between a vertical orientation and a horizontal orientation, in accordance with the orientation of the display housing 120. To perform the switching, the magnetic sensor 154 connected to the control unit 150 is housed in the main housing 110. The magnetic sensor 154 is placed on the center line of the main housing 110. Meanwhile, a left-side magnet 161a and a right-side magnet 161b are attached to the display housing 120. The left-side magnet 161a is placed so as to be located at the position corresponding to the position of the magnetic sensor 154 when the display housing 120 is rotated counterclockwise and is opened, as depicted in FIG. 11B. The right-side magnet 161b is placed so as to be located at the position corresponding to the position of the magnetic sensor 154 when the display housing 120 is rotated clockwise and is opened, as depicted in FIG. 11C.

The control unit 150 senses the magnetism of the left-side magnet 161a and the right-side magnet 161b, and determines the orientation of the display housing 120. Based on the result of the determination, the control unit 150 switches the display orientation of an image or a video image displayed on the display 121 between a vertical orientation and a horizontal orientation.

### <Display Housing>

As described above, the display housing 120 has the display 121, the left-side magnet 161a, and the right-side magnet 161b. The second member 5 is attached to the display housing 120, so that the display housing 120 is rotatably connected to the main housing 110. Since a very small number of components are mounted onto the display housing 120, the weight of the display housing 120 is very small.

### <Rotational Movement of Display Housing>

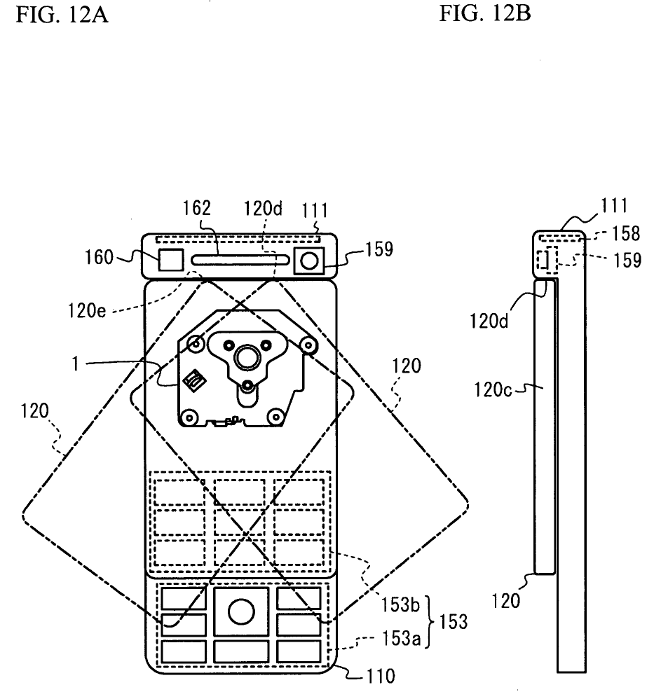

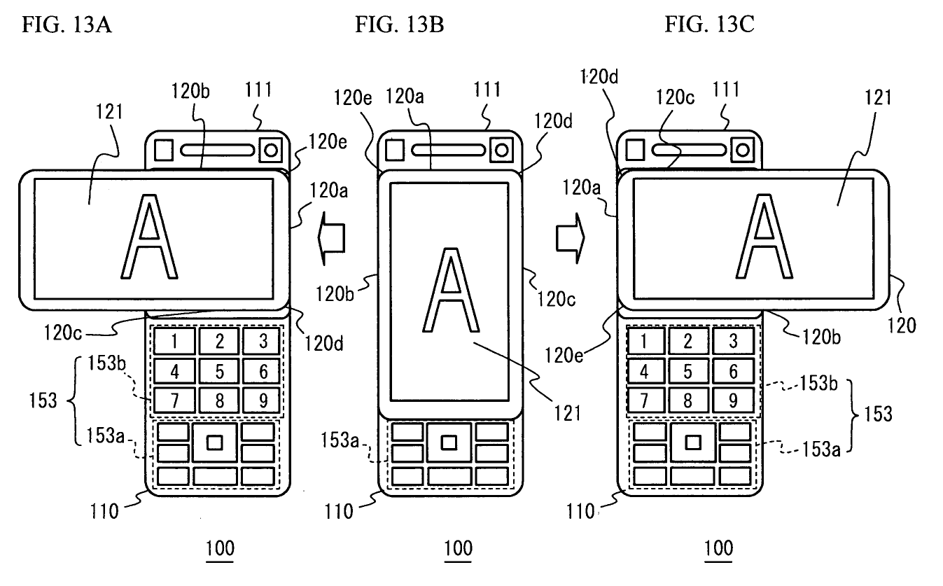

Referring now to FIGS. 12A through 13C, the rotational movement of the display housing 120 of the portable telephone device 100 is described. FIG. 12A illustrates a situation where the display housing 120 is rotating. FIG. 12B is a right-side view of the portable telephone device 100, with the display housing 120 being closed. FIG. 13A is a front view of the portable telephone device 100, with the display housing 120 being closed. FIG. 13B illustrates the portable telephone device 100, with the display housing 120 having rotated counterclockwise and being open. FIG. 13C illustrates the portable telephone device 100, with the display housing 120 having rotated clockwise and being open.

When the display housing 120 is turned from the situation illustrated in FIG. 13A into the situation illustrated in FIG. 13B, the display housing 120 is pushed counterclockwise. The display housing 120 then starts rotating. The corner portion 120d formed with the upper periphery 120a and the right-side periphery 120c of the display housing 120 is pressed against the wall portion 111, and rotates along the wall portion 111. At this point, the rotary shaft unit 11 moves away from the wall portion 111, pushed by the spring member 12.

When the rotation of the display housing 120 comes close to an end, the rotary shaft unit 11 moves toward the wall portion 111. Lastly, the right-side periphery 120c is brought into contact with the wall portion 111, and the display housing 120 is stabilized, as depicted in FIG. 13B.

In this situation, the magnetic sensor 154 senses the magnetism of the left-side magnet 161a, and switches the display orientation of the display 121 from a vertical orientation to a horizontal orientation, as depicted in FIG. 11B. As a result, the display 121 maintains a normal vision, though the display 121 has rotated 90°.

When the display housing 120 returns from the situation illustrated in FIG. 13B to the situation illustrated in FIG. 13A, the display housing 120 is pushed clockwise. The corner portion 120d of the display housing 120 then rotates along the wall portion 111, as depicted in FIG. 12A. The display housing 120 then returns to the closed state depicted in FIG. 13A.

When the display housing 120 is turned from the situation illustrated in FIG. 13A into the situation illustrated in FIG. 13C, the display housing 120 is pushed clockwise. The display housing 120 then starts rotating. The corner portion 120e formed with the upper periphery 120a and the left-side periphery 120b of the display housing 120 is pressed against the wall portion 111, and rotates along the wall portion 111. At this point, the rotary shaft unit 11 moves away from the wall portion 111, pushed by the spring member 12.

When the rotation of the display housing 120 comes close to an end, the rotary shaft unit 11 moves toward the wall portion 111. Lastly, the left-side periphery 120b is brought into contact with the wall portion 111, and the display housing 120 is stabilized, as depicted in FIG. 13C.

In this situation, the magnetic sensor 154 senses the magnetism of the right-side magnet 161b, and switches the display orientation of the display 121 from a vertical orientation to a horizontal orientation, as depicted in FIG. 11C. As a result, the display 121 maintains a normal vision, though the display 121 has rotated 90°.

When the display housing 120 returns from the situation illustrated in FIG. 13C to the situation illustrated in FIG. 13A, the display housing 120 is pushed counterclockwise. The corner portion 120e of the display housing 120 then rotates along the wall portion 111, as depicted in FIG. 12A. The display housing 120 then returns to the closed state depicted in FIG. 13A.

As described above, the portable telephone device 100 has the display housing 120 rotatably connected to the main housing 110 with the use of the rotative supporting unit 1. The thickness of the rotative supporting unit 1 is substantially equal to the sum of the thicknesses of the first member 2 and the second member 5. Accordingly, the portable telephone device 100 is very thin. Also, the rotative supporting unit 1 includes only a small number of components, and accordingly, the portable telephone device 100 can be made smaller.

In the portable telephone device 100, the display housing 120 rotates when simply pushed in a desired rotational direction. In this manner, the portable telephone device 100 is switched between a closed state and an open state. As described above, a very small number of components including the display 121, the left-side magnet 161a, and the right-side magnet 161b are mounted onto the display housing 120. Accordingly, the display housing 120 is lightweight, and can easily rotate. Since the display housing 120 is pressed against the wall portion 111 by the spring member 12 even during rotational movement, the display housing 120 spontaneously returns to a stable state after passing a predetermined point. Thus, the display housing 120 can be opened and closed with a very small force.

The speaker 162 should be placed as close as possible to the upper periphery of the portable telephone device 100, so as to achieve easy communications. In the portable telephone device 100 of this embodiment, the speaker 162 is built in the wall portion 111 located at the upper periphery of the main housing 110. Accordingly, the speaker 162 is fixed at such a position as to achieve easy communications.

### Second Embodiment

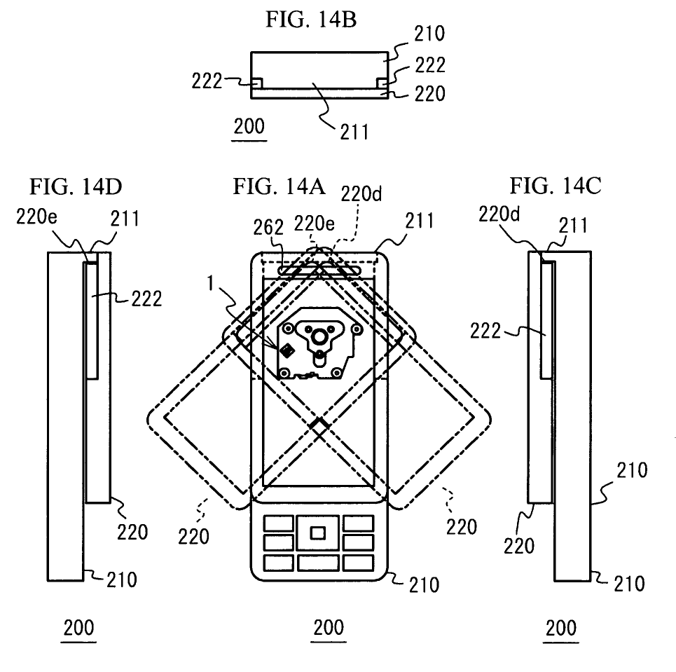

Referring now to FIGS. 14A through 16C, a portable telephone device 200 in accordance with a second embodiment of the present invention is described. The portable telephone device 200 of the second embodiment is the same as the portable telephone device 100 of the first embodiment, in having a main housing 210 and a display housing 220. The main housing 210 is the same as the main housing 110 of the first embodiment, in having a wall portion 211 protruding from the upper peripheral portion on the front face side of the main housing 210. The second embodiment is also the same as the first embodiment, in that the display housing 220 is rotatably connected to the main housing 210 with the use of the rotative supporting unit 1 of the first embodiment.

The portable telephone device 200 differs from the portable telephone device 100, in having a groove region 222 along the outer periphery of the back face of the display housing 220. The groove region 222 is designed to allow relative movement of the wall portion 211. Here, the back face of the display housing 220 faces the face of the main housing 210 to which the first member 2 is attached. In the following, mainly the different aspects in the structure and operations of the portable telephone device 200 will be described. The same components as those of the first embodiment are denoted in the drawings by the same reference numerals as those used in the first embodiment, and explanation of them is omitted here. The portable telephone device 200 does not include a camera unit and an optical sensor.

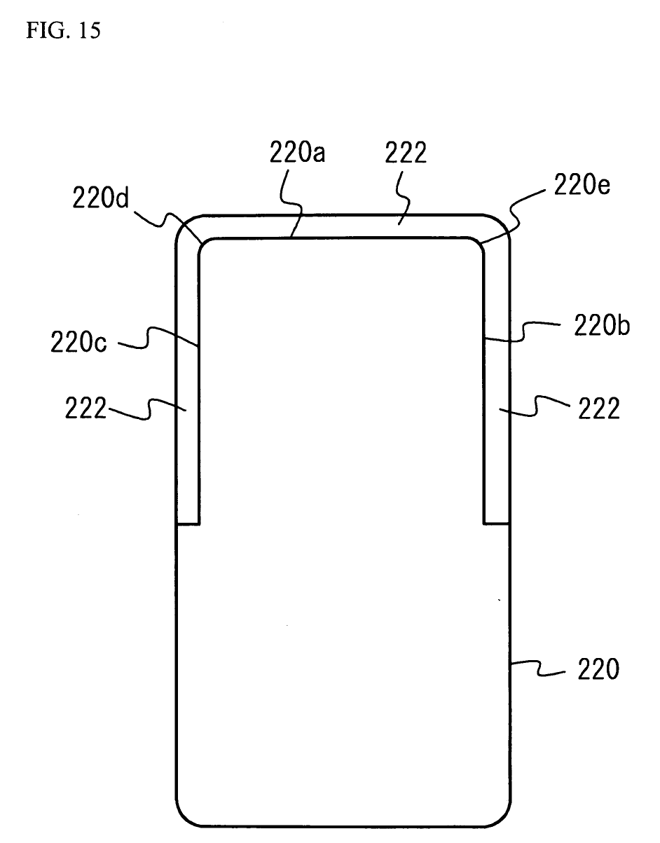

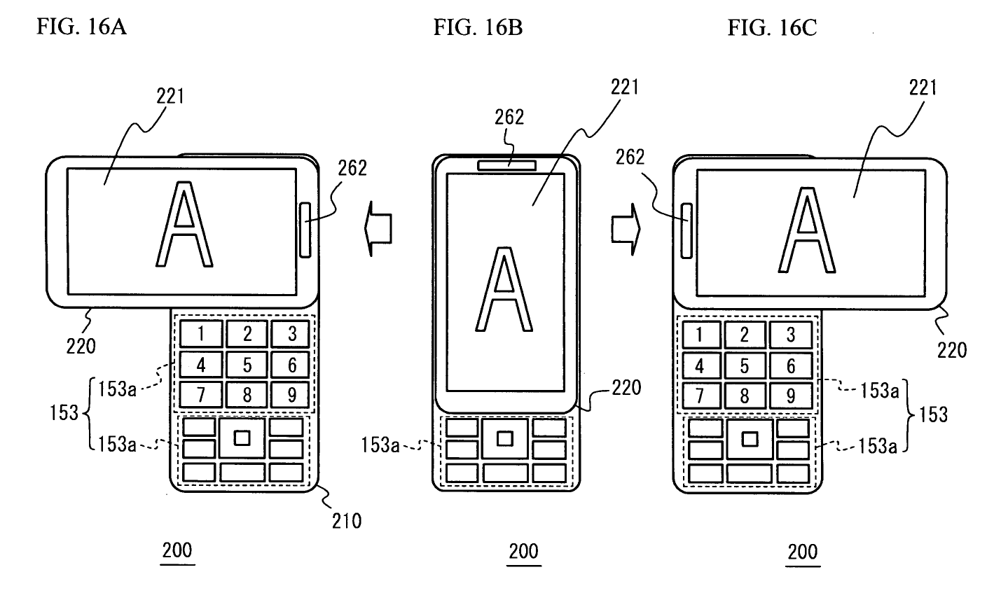

FIG. 14A illustrates a situation where the display housing 220 is rotating. FIG. 14B is a top view of the portable telephone device 200, with the display housing 220 being closed. FIG. 14C is a right-side view of the portable telephone device 200, with the display housing 220 being closed. FIG. 14D is a left-side view of the portable telephone device 200, with the display housing 220 being closed. FIG. 15 is a back side view of the display housing 220. FIG. 16A is a front view of the portable telephone device 200, with the display housing 220 being closed. FIG. 16B illustrates the portable telephone device 200, with the display housing 220 being rotated counterclockwise and being opened. FIG. 16C illustrates the portable telephone device 200, with the display housing 220 being rotated clockwise and being opened.

As depicted in the drawings, the portable telephone device 200 has the groove region 222 along the peripheral portion on the back face side of the display housing 220. The groove region 222 is designed to allow relative movement of the wall portion 211. The upper peripheral portion of the display housing 220 is placed over the wall portion 211. The groove region 222 is formed in a U-like shape along the peripheral portion of the back face of the display housing 220. An upper periphery 220a, a left-side periphery 220b, a right-side periphery 220c, and corner portions 220d and 220e are formed in the groove region 222. The upper periphery 220a, the left-side periphery 220b, the right-side periphery 220c, and the corner portions 220d and 220e are equivalent to the upper periphery 120a, the left-side periphery 120b, the right-side periphery 120c, and the corner portions 120d and 120e of the portable telephone device 100 of the first embodiment.

When the display housing 220 is turned from the situation illustrated in FIG. 16A into the situation illustrated in FIG. 16B, the display housing 220 is pushed counterclockwise. The display housing 220 then starts rotating. The corner portion 220d formed with the upper periphery 220a and the right-side periphery 220c of the display housing 220 is pressed against the wall portion 211, and rotates along the wall portion 211. The wall portion 211 has relative movement in the groove region 222. At this point, the rotary shaft unit 11 moves away from the wall portion 211, pushed by the spring member 12.

When the rotation of the display housing 220 comes close to an end, the rotary shaft unit 11 moves toward the wall portion 211. Lastly, the right-side periphery 220c is brought into contact with the wall portion 211, and the display housing 220 is stabilized.

When the display housing 220 returns from the situation illustrated in FIG. 16B to the situation illustrated in FIG. 16A, the display housing 220 is pushed clockwise. The corner portion 220d of the display housing 220 then rotates along the wall portion 211, as depicted in FIG. 14A. The display housing 220 then returns to the closed state depicted in FIG. 16A.

When the display housing 220 is turned from the situation illustrated in FIG. 16A into the situation illustrated in FIG. 16C, the display housing 220 is pushed clockwise. The display housing 220 then starts rotating. The corner portion 220e formed with the upper periphery 220a and the left-side periphery 220b of the display housing 220 is pressed against the wall portion 211, and rotates along the wall portion 211. The wall portion 211 has relative movement in the groove region 222. At this point, the rotary shaft unit 11 moves away from the wall portion 211, pushed by the spring member 12.

When the rotation of the display housing 220 comes close to an end, the rotary shaft unit 11 moves toward the wall portion 211. Lastly, the left-side periphery 220b is brought into contact with the wall portion 211, and the display housing 220 is stabilized.

When the display housing 220 returns from the situation illustrated in FIG. 16C to the situation illustrated in FIG. 16A, the display housing 220 is pushed counterclockwise. The corner portion 220e of the display housing 220 then rotates along the wall portion 211, as depicted in FIG. 14A. The display housing 220 then returns to the closed state depicted in FIG. 16A.

The switching of the display orientation of the display 221 between a vertical orientation and a horizontal orientation is performed in the same manner as in the portable telephone device 100 of the first embodiment.

As described above, the portable telephone device 200 has the display housing 220 rotatably connected to the main housing 210 with the use of the rotative supporting unit 1, like the portable telephone device 100 of the first embodiment. The thickness of the rotative supporting unit 1 is substantially equal to the sum of the thicknesses of the first member 2 and the second member 5. Accordingly, the portable telephone device 200 is very thin. Also, the rotative supporting unit 1 includes only a small number of components, and accordingly, the portable telephone device 200 can be made smaller.

The upper peripheral portion of the portable telephone device 200 has an extended shape and is located over the wall portion 211. Accordingly, the display 221 has a larger display area. Also, a speaker 262 is placed in the upper peripheral portion.

### Third Embodiment

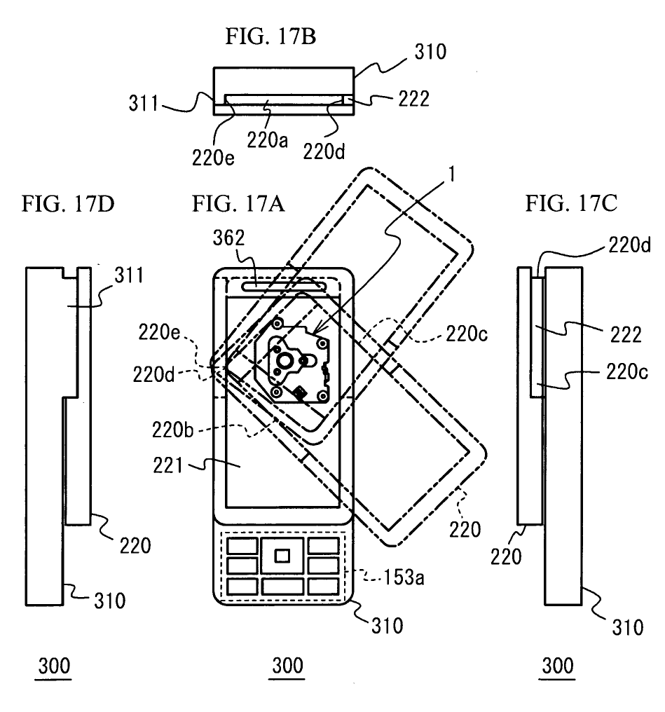

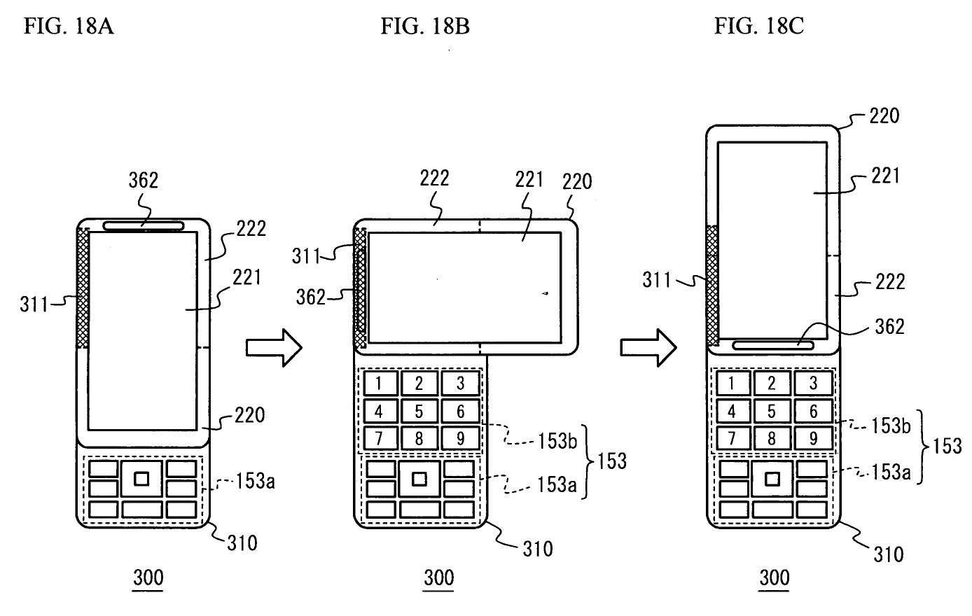

Referring now to FIGS. 17A through 18C, a portable telephone device 300 in accordance with a third embodiment of the present invention is described. The portable telephone device 300 of the third embodiment is the same as the portable telephone device 100 of the first embodiment, in having a main housing 310 and a display housing 220. The third embodiment is also the same as the first embodiment, in that the display housing 220 is rotatably connected to the main housing 310 with the use of the rotative supporting unit 1 of the first embodiment.

The following are the different aspects between the portable telephone device 300 and the portable telephone device 100. While the main housing 110 has the wall portion 111 protruding from the upper peripheral portion of the front face of the main housing 110, the main housing 310 has a wall portion 311 protruding from a side peripheral portion of the front face of the main housing 310. Accordingly, the direction of attachment of the rotative supporting unit 1 to the main housing 310 differs from that of the portable telephone device 100. The portable telephone device 300 also has a groove region 322 along the outer periphery of the back face of the display housing 220. The groove region 322 is designed to allow relative movement of the wall portion 311. In the following, mainly the different aspects in the structure and operations of the portable telephone device 300 will be described. The same components as those of the first embodiment are denoted in the drawings by the same reference numerals as those used in the first embodiment, and explanation of them is omitted here. Also, the display housing 220 is the same as that of the portable telephone device 200 of the second embodiment, and therefore, explanation of the display housing 220 is omitted here. The portable telephone device 300 does not include a camera unit and an optical sensor. A speaker 362 is placed at the upper periphery of the display housing 220.

FIG. 17A illustrates a situation where the display housing 220 is rotating. FIG. 17B is a top view of the portable telephone device 300, with the display housing 220 being closed. FIG. 17C is a right-side view of the portable telephone device 300, with the display housing 220 being closed. FIG. 17D is a left-side view of the portable telephone device 300, with the display housing 220 being closed. FIG. 18A is a front view of the portable telephone device 300, with the display housing 220 being closed. FIG. 18B illustrates the portable telephone device 300, with the display housing 220 being 90° rotated counterclockwise and being opened. FIG. 18C illustrates the portable telephone device 300, with the display housing 220 being 180° rotated counterclockwise and being opened.

As depicted in the drawings, the main housing 310 has the wall portion 311 at the left-side peripheral portion thereof. The rotative supporting unit 1 is placed so that the pushing force of the spring member 12 is directed toward the wall portion 311. The rotative supporting unit 1 connects the main housing 310 and the display housing 220. The display housing 220 rotates, with the corner portions 220d and 220e being pressed against the wall portion 311.

When the display housing 220 is turned from the situation illustrated in FIG. 18A into the situation illustrated in FIG. 18B, the display housing 220 is pushed counterclockwise. The display housing 220 then starts rotating. The corner portion 220e formed with the upper periphery 220a and the left-side periphery 220b of the display housing 220 is pressed against the wall portion 311, and rotates along the wall portion 311. The wall portion 311 has relative movement in the groove region 222. At this point, the rotary shaft unit 11 moves away from the wall portion 311, pushed by the spring member 12.

When the rotation of the display housing 220 comes close to an end, the rotary shaft unit 11 moves toward the wall portion 311. Lastly, the upper periphery 220a is brought into contact with the wall portion 311, and the display housing 220 is stabilized. Here, the display housing 220 is in a 90° open state.

When the display housing 220 returns from the situation illustrated in FIG. 18B to the situation illustrated in FIG. 18A, the display housing 220 is pushed clockwise. The corner portion 220e of the display housing 220 then rotates along the wall portion 311, as depicted in FIG. 17A. The display housing 220 then returns to the closed state depicted in FIG. 18A.

When the display housing 220 is turned from the situation illustrated in FIG. 18B into the situation illustrated in FIG. 18C, the display housing 220 is pushed counterclockwise. The display housing 220 then starts rotating. The corner portion 220d formed with the upper periphery 220a and the right-side periphery 220c of the display housing 220 is pressed against the wall portion 311, and rotates along the wall portion 311. The wall portion 311 has relative movement in the groove region 222. At this point, the rotary shaft unit 11 moves away from the wall portion 311, pushed by the spring member 12.

When the rotation of the display housing 220 comes close to an end, the rotary shaft unit 11 moves toward the wall portion 311. Lastly, the right-side periphery 220c is brought into contact with the wall portion 311, and the display housing 220 is stabilized. Here, the display housing 220 is in a 180° open state.

When the display housing 220 returns from the situation illustrated in FIG. 18C to the situation illustrated in FIG. 18B, the display housing 220 is pushed clockwise. The corner portion 220e of the display housing 220 then rotates along the wall portion 311, as depicted in FIG. 17A. The display housing 220 then returns to the 90° open state depicted in FIG. 18B.

The switching of the display orientation of the display 221 between a vertical orientation and a horizontal orientation is realized by changing the positions of the magnetic sensor and the magnets.

As described above, the portable telephone device 300 has the display housing 220 rotatably connected to the main housing 310 with the use of the rotative supporting unit 1, like the portable telephone device 100 of the first embodiment. The thickness of the rotative supporting unit 1 is substantially equal to the sum of the thicknesses of the first member 2 and the second member 5. Accordingly, the portable telephone device 300 is very thin. Also, the rotative supporting unit 1 includes only a small number of components, and accordingly, the portable telephone device 300 can be made smaller.

Also, the wall portion 311 is provided at a side peripheral portion of the main housing, and the display housing 220 is pressed against the wall portion 311. Accordingly, the display housing 220 can be rotated and turned from a closed state into a 90° open state, and be further 90° rotated and turned into a 180° open state.

The present invention is not limited to the specifically disclosed embodiments, but other embodiments and variations may be made without departing from the scope of the present invention.

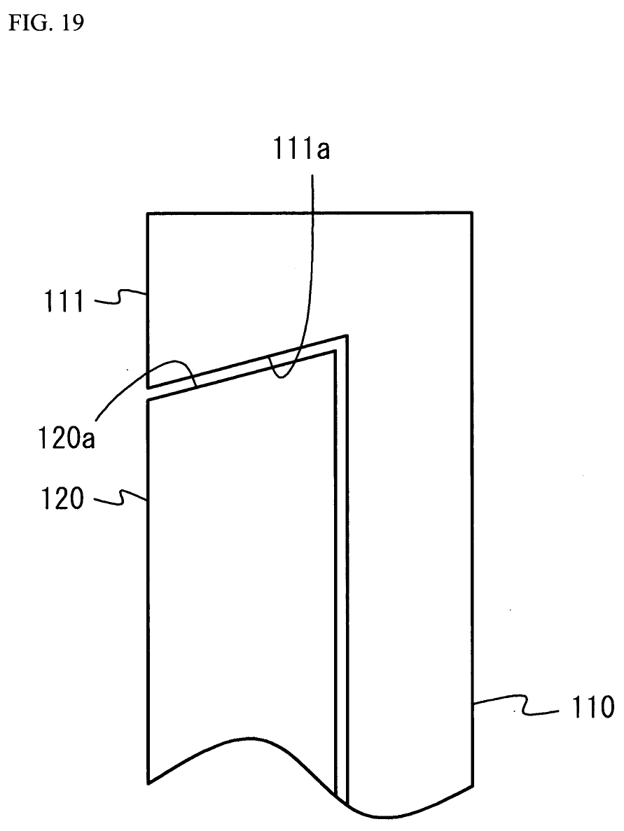

For example, the wall portion 111 depicted in FIG. 19 may have a groove 111a with which the upper periphery 120a of the display housing 120 is to be engaged. With the upper periphery 120a of the display housing 120 being engaged with the wall portion 111 in this manner, detachment of the display housing 120 can be prevented. Here, the cross-sectional shape of the upper periphery 120a of the display housing 120 and the cross-sectional shape of the groove 111a may be tapered shapes.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A device comprising:
a first housing that has a wall portion protruding from a front face side thereof;
a second housing that has a portion pressed against the wall portion, and is overlapped on the front face side of the first housing, the second housing being rotatable, with the portion being pressed against the wall portion;
a first member that is attached to a face of the first housing, the face facing the second housing;
a second member that is attached to a face of the second housing, the face facing the face having the first member attached thereto;
a rotary shaft unit that allows the second member to slidably move with respect to the first member, and supports the second member in a rotatable manner; and
a pushing unit that pushes the second housing, so that the portion of the second housing is pressed against the wall portion,
wherein the first member has a guide groove that has the rotary shaft unit slidably attached thereto, the rotary shaft unit moving away from the wall portion or approaching the wall portion when the second housing rotates, with the portion being pressed against the wall portion.

2. The device as claimed in claim 1, wherein the wall portion is formed at an upper peripheral portion of the first housing.

3. The device as claimed in claim 1, wherein the wall portion is formed at a side peripheral portion of the first housing.

4. The device as claimed in claim 1, wherein the second housing has a groove region formed along a peripheral portion of a back face of the second housing, the groove region allowing relative movement of the wall portion.

5. The device as claimed in claim 1, wherein the wall portion has a groove to be engaged with a peripheral portion of the second housing.

6. A portable terminal device comprising:
the device as claimed in claim 1, which device has the first housing as a main housing and the second housing as a display housing; and
a speaker that is placed in the wall portion.

7. A rotative supporting unit comprising:
a first member that is attached to a first housing;
a second member that is attached to a second housing, the second member facing the first member;
a rotary shaft unit that allows the second member to slidably move with respect to the first member, and supports the second member in a rotatable manner; and
a pushing unit that pushes the second member in a direction of the sliding of the second member,
wherein the first member has a guide groove that has the rotary shaft unit slidably attached thereto, and helps the sliding movement of the rotary shaft unit.
